(19) United States
(12) Patent Application Publication
(10) Pub. No.: US 2013/0062666 A1
(43) Pub. Date: Mar. 14, 2013

(54) COMPOUND SEMICONDUCTOR DEVICE AND METHOD FOR MANUFACTURING THE SAME

(71) Applicant: Tadahiro IMADA, Kawasaki (JP)

(72) Inventor: Tadahiro IMADA, Kawasaki (JP)

(73) Assignee: FUJITSU LIMITED, Kawasaki-shi (JP)

(21) Appl. No.: 13/557,322

(22) Filed: Jul. 25, 2012

(30) Foreign Application Priority Data
Sep. 13, 2011 (JP) 2011-199657

(51) Int. Cl. H01L 29/778; H01L 21/335; H01L 29/10

(52) U.S. Cl. 257/194; 257/657; 438/172; 257/E29.246; 257/E21.403; 257/E29.05

(57) ABSTRACT

A compound semiconductor device includes a substrate; and a compound semiconductor layer disposed over the substrate, wherein the compound semiconductor layer includes a first region having first conductivity-type carriers generated by activating a first impurity and also includes a second region having carriers at lower concentration as compared to the first region, the carriers being generated by activating a second impurity which is the same type as the first impurity.

### CROSS-REFERENCE TO RELATED APPLICATION

This application is based upon and claims the benefit of priority of the prior Japanese Patent Application No. 2011-199657, filed on Sep. 13, 2011 the entire contents of which are incorporated herein by reference.

### FIELD

The embodiments discussed herein are related to a compound semiconductor device and a method for manufacturing the same.

### BACKGROUND

Nitride semiconductors have properties such as high saturated electron drift velocity and a wide band gap. Therefore, the nitride semiconductors are being attempted to be used for high-voltage, high-power semiconductor devices by making use of such properties. For example, GaN, which is a nitride semiconductor, has a band gap of 3.4 eV, which is greater than the band gap (1.1 eV) of Si and the band gap (1.4 eV) of GaAs. Therefore, GaN has high breakdown field strength and is a highly promising material for semiconductor devices for power supplies for obtaining high-voltage operation and high power.

A large number of reports have been made about semiconductor devices, such as field-effect transistors, containing nitride semiconductors and particularly about high electron mobility transistors (HEMTs). Among GaN-based HEMTs, for example, an AlGaN/GaN-HEMT including an electron travel layer made of GaN and an electron supply layer made of AlGaN is attracting attention. In the AlGaN/GaN-HEMT, strain due to the difference in lattice constant between GaN and AlGaN is caused in AlGaN. A high-concentration two-dimensional electron gas (2DEG) is obtained due to piezoelectric polarization induced by such strain and the spontaneous polarization of AlGaN. Therefore, the AlGaN/GaN-HEMT is promising as a high-efficiency switching element, a high-voltage power device for electric vehicles, or the like.

However, compound semiconductor devices made of a compound semiconductor such as a nitride semiconductor are limited in available structure as compared to Si semiconductor devices such as transistors made of Si.

Japanese Laid-open Patent Publication Nos. 2010-153493 and 2009-49288 are examples of related art.

### SUMMARY

According to an aspect of the embodiments, an apparatus includes a substrate; and a compound semiconductor layer disposed over the substrate, wherein the compound semiconductor layer includes a first region having first conductivity-type carriers generated by activating a first impurity and also includes a second region having carriers at lower concentration as compared to the first region, the carriers being generated by activating a second impurity which is the same type as the first impurity.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a sectional view of a compound semiconductor device according to a first embodiment;

FIGS. 2A to 2D are sectional views illustrating operations of a method for manufacturing the compound semiconductor device according to the first embodiment;

FIG. 3 is a sectional view of a compound semiconductor device according to a second embodiment;

FIGS. 4A and 4B are full views of the compound semiconductor device according to the second embodiment;

FIGS. 5A to 5L are sectional views illustrating operations of a method for manufacturing the compound semiconductor device according to the second embodiment;

FIG. 6 is a sectional view of a compound semiconductor device according to a third embodiment;

FIG. 7 is a sectional view of a compound semiconductor device according to a fourth embodiment;

FIGS. 8A and 8B are full views of the compound semiconductor device according to the fourth embodiment;

FIGS. 9A to 9L are sectional views illustrating operations of a method for manufacturing the compound semiconductor device according to the fourth embodiment;

FIG. 10 is a sectional view of a compound semiconductor device according to a fifth embodiment;

FIGS. 11A and 11B are full views of the compound semiconductor device according to the fifth embodiment;

FIGS. 12A to 12H are sectional views illustrating operations of a method for manufacturing the compound semiconductor device according to the fifth embodiment;

FIG. 13 is a wiring diagram of a PFC circuit according to a sixth embodiment;

FIG. 14 is a wiring diagram of a power supply system according to a seventh embodiment;

FIG. 15 is a wiring diagram of a high-frequency amplifier according to an eighth embodiment;

FIG. 16 is a sectional view of a semiconductor device according to a first reference example;

FIGS. 17A and 17B are graphs illustrating results of a first experiment;

FIG. 18 is a sectional view of a semiconductor device according to a second reference example;

FIGS. 19A and 19B are graphs illustrating results of a second experiment;

FIG. 20 is a sectional view of a semiconductor device according to a third reference example;

FIG. 21 is a graph illustrating results of a third experiment; and

FIG. 22 is an illustration depicting correlations between the irradiation intensity of a laser beam, the density of generated carriers, and the activation rate.

### DESCRIPTION OF EMBODIMENTS

Hereinafter, embodiments are described in detail with reference to the attached drawings.

(Comparisons between Si semiconductor devices and compound semiconductor devices)

For Si semiconductor devices, the activation of an impurity used to form an n- or p-type region may be readily controlled. This is because carriers may be readily generated in such a manner that the impurity is ion-implanted into a Si substrate or the like and is activated by annealing. Since the activation of the impurity may be readily controlled, various activated impurity regions may be provided in a direction (in-plane direction) parallel to a surface of the Si substrate.

On the other hand, for compound semiconductor devices, it is difficult to generate carriers by implanting ions into a compound semiconductor layer. Therefore, in usual, the compound semiconductor layer is doped with an impurity during the epitaxial growth of the compound semiconductor layer and the impurity is then activated by annealing. In the case of growing GaN semiconductor layers, for example, Si is used as an n-type impurity and Mg or C is used as a p-type impurity. However, these impurities, particularly p-type impurities, are unlikely to be activated as compared to impurities used in the Si semiconductor devices. Therefore, it is not easy to control the concentration of carriers; hence, compound semiconductor devices made of a compound semiconductor such as a nitride semiconductor are limited in available structure as compared to the Si semiconductor devices.

In, for example, AlGaN/GaN-HEMTs, p-type regions having different carrier concentrations each suitable for achieving a normally-off operation or reduced parasitic capacitance have to be arranged in an in-plane direction in some cases. However, it is difficult for conventional techniques to achieve such a structure. If p-type regions different in carrier concentration from each other may be contacted with each other in an in-plane direction, a Schottky diode may be theoretically obtained. However, it is difficult for conventional techniques to achieve such a structure. In embodiments below, these structures may be achieved.

### First Embodiment

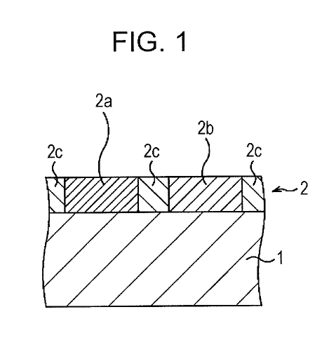

A first embodiment is described below. FIG. 1 is a sectional view of a compound semiconductor device according to the first embodiment.

In the first embodiment, a compound semiconductor layer 2 is disposed over a substrate 1 as illustrated in FIG. 1. The compound semiconductor layer 2 includes a high-carrier concentration region 2a containing carriers generated by activating an impurity, a low-carrier concentration region 2b which contains carriers generated by activating the same impurity as that used in the high-carrier concentration region 2a and which has a carrier concentration lower than that of the high-carrier concentration region 2a, and an inactive region 2c in which no impurity is activated. The high-carrier concentration region 2a is an example of a first region. The low-carrier concentration region 2b is an example of a second region.

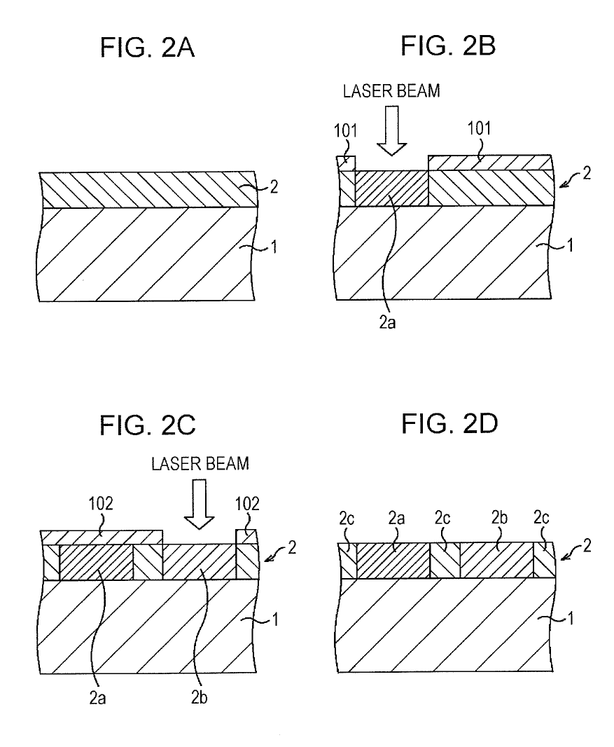

The compound semiconductor device, which has such a configuration, may manufactured by a method below. FIGS. 2A to 2D are sectional views illustrating operations of a method for manufacturing the compound semiconductor device according to the first embodiment.

First, as illustrated in FIG. 2A, the compound semiconductor layer 2 is formed over the substrate 1 so as to contain the impurity. The compound semiconductor layer 2 is formed by, for example, epitaxial growth. Next, as illustrated in FIG. 2B, a mask 101 is formed on the compound semiconductor layer 2 so as to have an opening open to a region which is to be formed into the high-carrier concentration region 2a. The compound semiconductor layer 2 is irradiated with a laser beam through the opening. As a result, a portion of the compound semiconductor layer 2 that is irradiated with the laser beam is increased in temperature, the impurity is activated, and therefore carriers are generated. This portion is converted into the high-carrier concentration region 2a. Thereafter, as illustrated in FIG. 2C, the mask 101 is removed and a mask 102 is then formed on the compound semiconductor layer 2 so as to have an opening open to a region which is to be formed into the low-carrier concentration region 2b. The compound semiconductor layer 2 is irradiated with a laser beam through this opening. In this operation, the irradiation intensity of the laser beam is adjusted to be lower than the irradiation intensity of the laser beam used to form the high-carrier concentration region 2a. As a result, a portion of the compound semiconductor layer 2 that is irradiated with the laser beam is increased in temperature, the impurity in this portion is less activated than the impurity in the portion used to form the high-carrier concentration region 2a, and therefore carriers are generated at low concentration. This portion is converted into the low-carrier concentration region 2b. As illustrated in FIG. 2D, the mask 102 is removed. A portion of the compound semiconductor layer 2 that is irradiated with no laser beam and that contains no carriers corresponds to the inactive region 2c.

According to this method, an activated impurity region with a desired carrier concentration may be readily formed at a desired position. Thus, the high-carrier concentration region 2a and the low-carrier concentration region 2b, which are arranged at different positions in a direction parallel to a surface of the substrate 1, may used as activated impurity regions of a transistor, a Schottky diode, or the like. This allows the compound semiconductor device to have an increased degree of structural freedom.

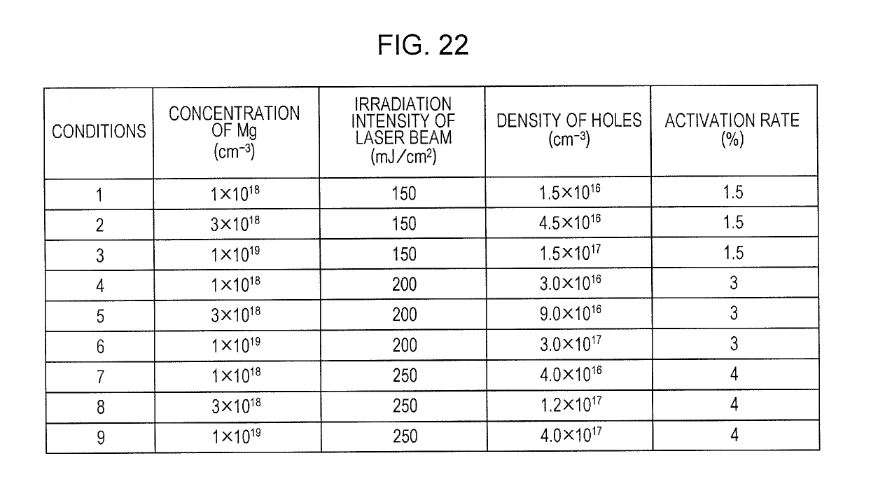

The inventor has investigated correlations between the concentration of the impurity in the compound semiconductor layer 2, the irradiation intensity of a laser beam, the density of generated carriers, and the activation rate. The results are summarized in a table illustrated in FIG. 22. The impurity used was Mg and a source of the laser beam used was a KrF laser. Since Mg was used as the impurity, the generated carriers were holes.

The results (the density of the holes and the activation rate) summarized in the table indicate that when the concentration of Mg is fixed, the increase in irradiation intensity of the laser beam increases the density of the holes and the activation rate. When the irradiation intensity of the laser beam is fixed, the increase in concentration of Mg increases the density of the holes; however, the activation rate remains fixed regardless of the increase in concentration of Mg. From these results, it is clear that if a plurality of regions of a compound semiconductor layer containing an impurity are irradiated with a laser beam at different irradiation intensities, then these regions are allowed to have different carrier densities.

Various lasers may be used as the laser beam source. Examples of the laser beam source include semiconductor lasers, nitrogen lasers, ArF lasers, KrF lasers, ruby lasers, YAG lasers, Nd:YAG lasers, titanium sapphire lasers, dye lasers, carbon dioxide lasers, helium-neon lasers, argon ion lasers, and excimer lasers. In order to activate the impurity in the compound semiconductor layer 2, the temperature of a portion of the compound semiconductor layer 2 may be increased in such a manner that this portion is irradiated with an electron beam or an ion beam instead of the laser beam. This applies to embodiments below.

### Second Embodiment

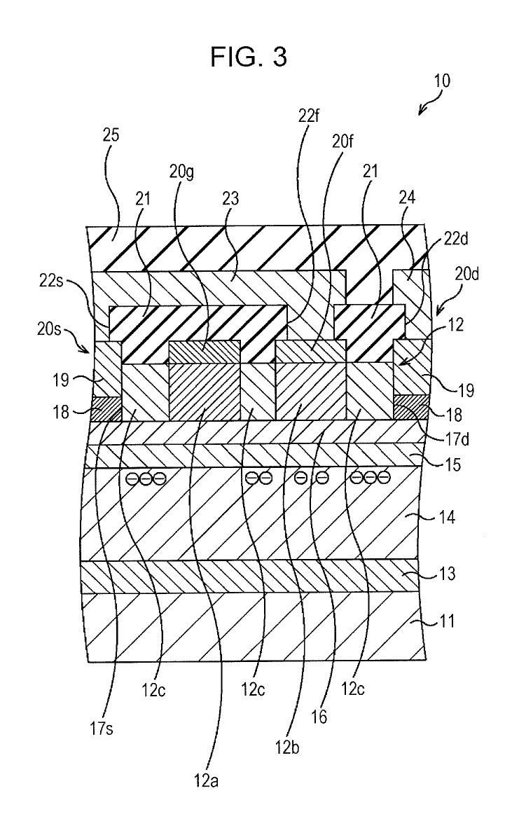

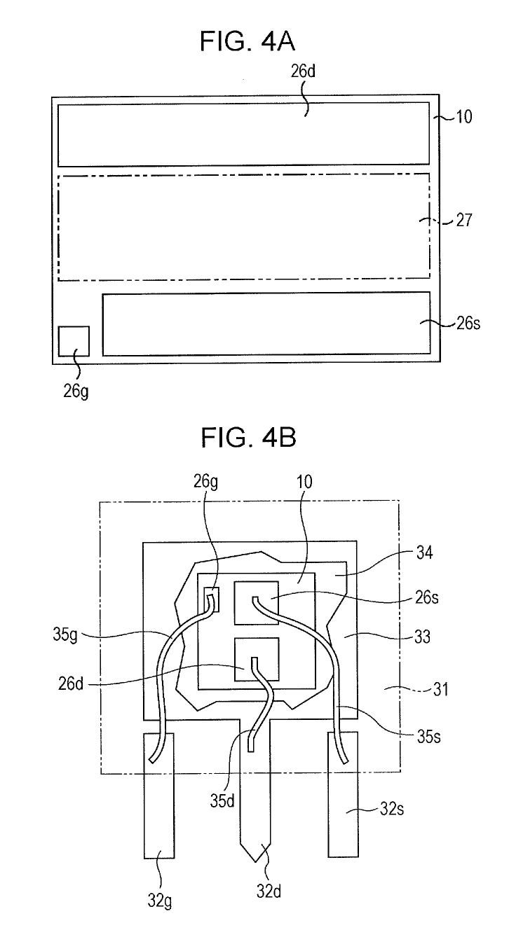

A second embodiment is described below. FIG. 3 is a sectional view of a compound semiconductor device according to the second embodiment. FIGS. 4A and 4B are full views of the compound semiconductor device according to the second embodiment.

In the compound semiconductor device 10 according to the second embodiment, a buffer layer 13, an electron travel layer 14, an intermediate layer 15, an electron supply layer 16, and a Mg-doped compound semiconductor layer 12 are arranged in series on a substrate 11 as illustrated in FIG. 3. Examples of the substrate 11 include Si substrates, sapphire substrates, GaAs substrates, SiC substrates, and GaN substrates. The substrate 11 may be insulating, semi-insulating, or conductive. The buffer layer 13 is, for example, an AlN layer and has a thickness of, for example, about 0.1 μm. The electron travel layer 14 is, for example, an intentionally undoped i-GaN layer and has a thickness of, for example, about 3 μm. The intermediate layer 15 is, for example, an intentionally undoped i-Al_{0.25}Ga_{0.75}N layer and has a thickness of, for example, about 5 nm. The electron supply layer 16 is, for example, an n-type n-Al_{0.25}Ga_{0.75}N layer and has a thickness of, for example, about 30 nm. The electron supply layer 16 contains, for example, Si, which is an n-type impurity. The Mg-doped compound semiconductor layer 12 is, for example, a GaN layer doped with Mg at a concentration of about 1×10¹⁹ cm⁻³ and has a thickness of, for example, about 10 nm.

The Mg-doped compound semiconductor layer 12 has openings 17s and 17d. The opening 17s contains a source electrode 20s and the opening 17d contains a drain electrode 20d. The source electrode 20s and the drain electrode 20d each include a Ta film 18 in contact with the electron supply layer 16 and an Al film 19 disposed on the Ta film 18. The Mg-doped compound semiconductor layer 12 includes a high-carrier concentration region 12a and low-carrier concentration region 12b located between the source electrode 20s and the drain electrode 20d. The high-carrier concentration region 12a and the low-carrier concentration region 12b are those formed by activating Mg, which is a p-type impurity, contained in the Mg-doped compound semiconductor layer 12. The high-carrier concentration region 12a is more strongly activated than the low-carrier concentration region 12b. Thus, the high-carrier concentration region 12a has a carrier concentration higher than the carrier concentration of the low-carrier concentration region 12b. The high-carrier concentration region 12a is located closer to the source electrode 20s than the low-carrier concentration region 12b. Hence, the low-carrier concentration region 12b is located between the high-carrier concentration region 12a and the drain electrode 20d. The Mg-doped compound semiconductor layer 12 further includes inactive regions 12c in which Mg is not activated. The inactive regions 12c are each located between the source electrode 20s and the high-carrier concentration region 12a, between high-carrier concentration region 12a and the low-carrier concentration region 12b, or between the low-carrier concentration region 12b and the drain electrode 20d. The high-carrier concentration region 12a is overlaid with a gate electrode 20g. The low-carrier concentration region 12b is overlaid with a field plate electrode 20f. The gate electrode 20g and the field plate electrode 20f each include a Ni film in contact with the high-carrier concentration region 12a or the low-carrier concentration region 12b and an Au film disposed on the Ni film.

The Mg-doped compound semiconductor layer 12, the source electrode 20s, the drain electrode 20d, the gate electrode 20g, and the field plate electrode 20f are covered with an insulating layer 21. The insulating layer 21 is, for example, a silicon nitride film. The insulating layer 21 has an opening 22s through which at least one portion of the source electrode 20s is exposed, an opening 22d through which at least one portion of the drain electrode 20d is exposed, and an opening 22f through which at least one portion of the field plate electrode 20f is exposed. A wiring line 23 extends through the openings 22s and 22f to connect the source electrode 20s and the field plate electrode 20f to each other and extends on the insulating layer 21. A wiring line 24 connected to the drain electrode 20d also extends on the insulating layer 21. The insulating layer 21 further has an opening through which at least one portion of the gate electrode 20g is exposed. A wiring line connected to the gate electrode 20g also extends on the insulating layer 21. A passivation layer 25 is disposed on the insulating layer 21 and covers the wiring lines 23 and 24. The passivation layer 25 is, for example, a silicon nitride film.

The compound semiconductor device 10, which is configured as described above, functions as a HEMT. That is, a 2DEG is generated in a surface portion of the electron travel layer 14 and a current flows between the source electrode 20s and the drain electrode 20d depending on the voltage applied to the gate electrode 20g. The high-carrier concentration region 12a contains holes, which are carriers, at high concentration. Therefore, little amount of the 2DEG is present in a part of the surface portion of the electron travel layer 14, the part being located under the high-carrier concentration region 12a. Thus, the compound semiconductor device 10 may operate in a normally-off mode.

If the concentration of the 2DEG present between the gate electrode 20g and the drain electrode 20d in plan view is globally high, then a depletion layer is unlikely to expand and it is difficult to ensure sufficient dielectric strength. However, in this embodiment, the low-carrier concentration region 12b contains holes at low concentration and is located between the gate electrode 20g and the drain electrode 20d in plan view; hence, a region under the low-carrier concentration region 12b has a 2DEG concentration lower than that of the surrounding region. Thus, a depletion layer is likely to expand under the low-carrier concentration region 12b, the concentration of an electric field may be suppressed, and increased dielectric strength may be achieved. When the carrier concentration of the low-carrier concentration region 12b is substantially equal to that of the high-carrier concentration region 12a, the 2DEG disappears and therefore no current flows.

In this embodiment, the Mg-doped compound semiconductor layer 12 is present between the insulating layer 21 and the 2DEG and the interface between the insulating layer 21 and the Mg-doped compound semiconductor layer 12 is relatively far away from the 2DEG. This allows a reduction in dielectric strength due to the concentration of an electric field to be suppressed.

The field plate electrode 20f is connected to the source electrode 20s and therefore may reduce the parasitic capacitance Cgs between the gate electrode 20g and the source electrode 20s and the parasitic capacitance Cgd between the gate electrode 20g and the drain electrode 20d. This enables high-speed operation.

As illustrated in FIG. 4A, the wiring line 23 is connected to a source pad 26s which is an external terminal of the compound semiconductor device 10 and the wiring line 24 is connected to a drain pad 26d which is an external terminal of the compound semiconductor device 10. A wiring line connected to the gate electrode 20g is connected to a gate pad 26g which is an external terminal of the compound semiconductor device 10. A region located between the source pad 26s and the drain pad 26d in plan view substantially corresponds to a transistor region 27 in which the 2DEG is present.

For packaging, as illustrated in FIG. 4B, the back surface of the compound semiconductor device 10 is fixed to a land (die pad) 33 with a die attaching agent 34 such as solder. One end of a wire 35d such as an Al wire is connected to the drain pad 26d and the other end of the wire 35d is connected to a drain lead 32d integral with the land 33. One end of a wire 35s such as an Al wire is connected to the source pad 26s and the other end of the wire 35s is connected to a source lead 32s independent of the land 33. One end of a wire 35g such as an Al wire is connected to the gate pad 26g and the other end of the wire 35g is connected to a gate lead 32g independent of the land 33. The land 33, the compound semiconductor device 10, and the like are packaged with a molding resin 31 such that a portion of the gate lead 32g, a portion of the drain lead 32d, and a portion of the source lead 32s protrude.

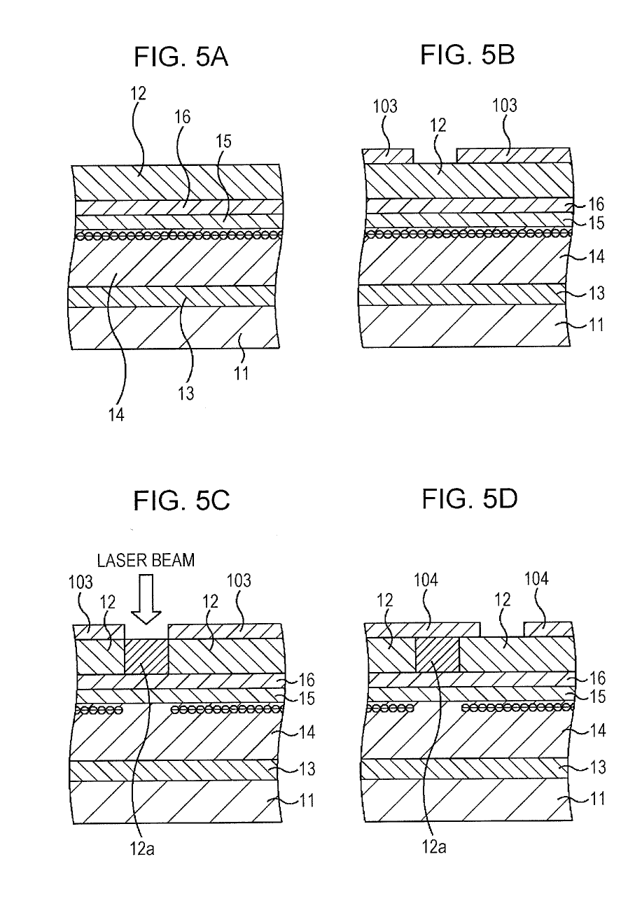

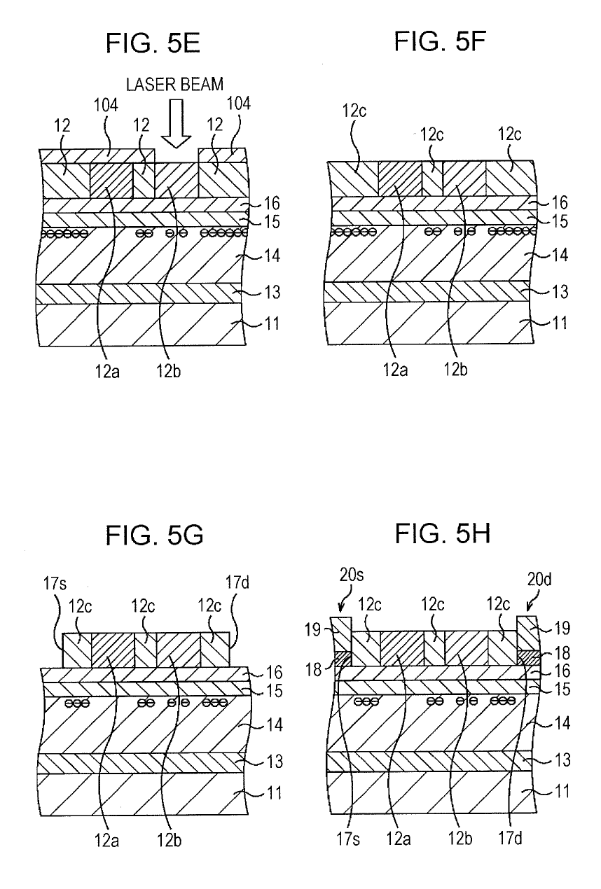

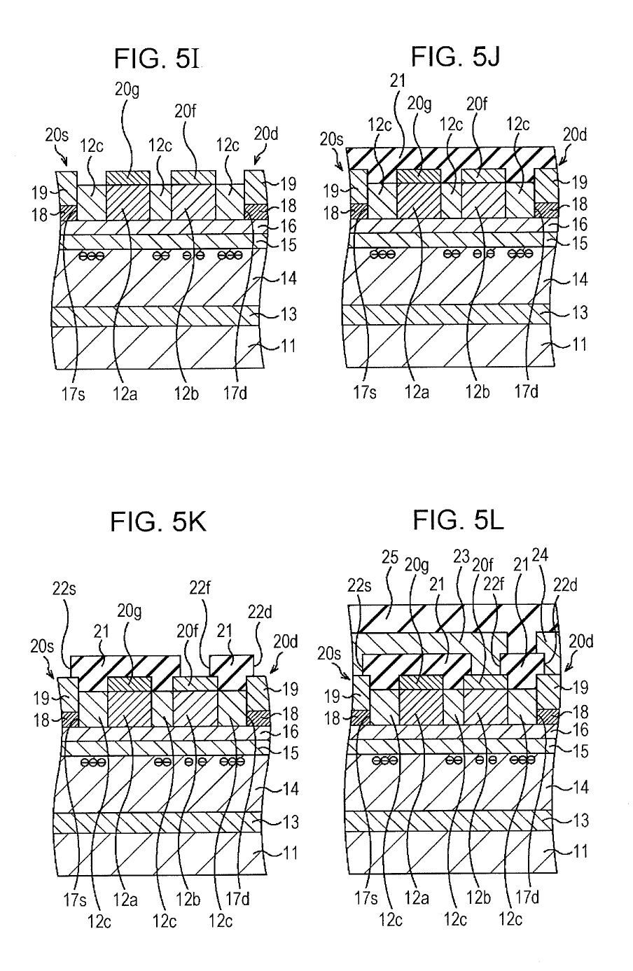

A method for manufacturing the compound semiconductor device 10 according to the second embodiment is described below. FIGS. 5A to 5L are sectional views illustrating operations of the method for manufacturing the compound semiconductor device 10 according to the second embodiment.

First, as illustrated in FIG. 5A, the buffer layer 13, the electron travel layer 14, the intermediate layer 15, the electron supply layer 16, and the Mg-doped compound semiconductor layer 12 are formed in series on the substrate 11 by, for example, a crystal growth process such as metal-organic chemical vapor deposition (MOCVD) or molecular beam epitaxy (MBE). As a result, the 2DEG is generated in the surface portion of the electron travel layer 14 at high concentration.

The following mixture is used to form these layers: a gas mixture containing, for example, a trimethyl aluminum gas which is a source of Al, a trimethyl gallium gas which is a source of Ga, and an ammonia gas which is a source of N. The supply and flow rate of each of the trimethyl aluminum gas and the trimethyl gallium gas are appropriately controlled depending on the composition of a corresponding one of these layers. The flow rate of the ammonia gas, which is common to these layers, is about 100 ccm to 10 LM. The growth pressure is, for example, about 50 Torr to 300 Torr. The growth temperature is, for example, about 1,000° C. to 1,200° C. In the case of growing an n-type compound semiconductor layer, for example, a SiH₄ gas, which contains Si, is added to the gas mixture at a given flow rate and a compound semiconductor layer is doped with Si. The concentration of Si in the compound semiconductor layer is preferably about 1×10¹⁸ cm⁻³ to 1×10²⁰ cm⁻³ and more preferably about 5×10¹⁸ cm⁻³.

Next, as illustrated in FIG. 5B, a mask 103 such as a metal mask is formed on the Mg-doped compound semiconductor layer 12 so as to have an opening open to a region which is to be formed into the high-carrier concentration region 12a. As illustrated in FIG. 5C, the Mg-doped compound semiconductor layer 12 is irradiated with a laser beam through the opening. A source of the laser beam used is, for example, a KrF excimer laser. The irradiation intensity of the laser beam is, for example, about 250 mJ/cm². As a result, a portion of the Mg-doped compound semiconductor layer 12 that is irradiated with the laser beam is increased in temperature, Mg is activated, and therefore holes are generated. This portion is converted into the high-carrier concentration region 12a. Since the high-carrier concentration region 12a is formed, the 2DEG disappears from under the high-carrier concentration region 12a.

Thereafter, as illustrated in FIG. 5D, the mask 103 is removed and a mask 104 such as a metal mask is then formed on the Mg-doped compound semiconductor layer 12 so as to have an opening open to a region which is to be formed into the low-carrier concentration region 12b. As illustrated in FIG. 5E, the Mg-doped compound semiconductor layer 12 is irradiated with a laser beam through this opening. A source of the laser beam used is, for example, a KrF excimer laser. In this operation, the irradiation intensity of the laser beam is lower than the irradiation intensity of the laser beam used to form the high-carrier concentration region 12a and is, for example, about 100 mJ/cm². As a result, a portion of the Mg-doped compound semiconductor layer 12 that is irradiated with the laser beam is increased in temperature, Mg in this portion is less activated than Mg in the portion used to form the high-carrier concentration region 12a, and therefore holes are generated at low concentration. This portion is converted into the low-carrier concentration region 12b. Since the low-carrier concentration region 12b is formed, the concentration of the 2DEG under the low-carrier concentration region 12b is reduced.

Next, as illustrated in FIG. 5F, the mask 104 is removed. Portions of the Mg-doped compound semiconductor layer 12 that are irradiated with no laser beam and that contain no carriers correspond to the inactive regions 12c. As illustrated in FIG. 5G, the opening 17s for the source electrode 20s and the opening 17d for the drain electrode 20d are formed in the Mg-doped compound semiconductor layer 12. Thereafter, as illustrated in FIG. 5H, the source electrode 20s and the drain electrode 20d are formed in the opening 17s and the opening 17d, respectively, by, for example, a lift-off process. The source electrode 20s and the drain electrode 20d are formed in such a manner that the Ta film 18 and the Al film 19 are formed by, for example, a vapor deposition process. As illustrated in FIG. 5I, the gate electrode 20g and the field plate electrode 20f are formed on the high-carrier concentration region 12a and the low-carrier concentration region 12b, respectively, by, for example, a lift-off process. The gate electrode 20g and the field plate electrode 20f are formed in such a manner that the Ni film and the Au film are formed by, for example, a vapor deposition process.

Next, as illustrated in FIG. 5J, the insulating layer 21 is formed over the Mg-doped compound semiconductor layer 12, the source electrode 20s, the drain electrode 20d, the gate electrode 20g, and the field plate electrode 20f. Thereafter, as illustrated in FIG. 5K, the opening 22s, the opening 22d, and the opening 22f are formed in the insulating layer 21 such that at least one portion of the source electrode 20s is exposed through the opening 22s, at least one portion of the drain electrode 20d is exposed through the opening 22d, and at least one portion of the field plate electrode 20f is exposed through the opening 22f. As illustrated in FIG. 5L, the wiring line 23 and the wiring line 24 are formed on the insulating layer 21 such that the wiring line 23 extends through the openings 22s and 22f to connect the source electrode 20s and field plate electrode 20f to each other and the wiring line 24 is connected to the drain electrode 20d. An opening through which at least one portion of the gate electrode 20g is exposed is formed in the insulating layer 21 and a wiring line connected to the gate electrode 20g is formed on the insulating layer 21. The passivation layer 25 is then formed over the wiring lines 23 and 24.

As described above, the compound semiconductor device (HEMT) 10 may be manufactured so as to have a structure illustrated in FIG. 3.

### Third Embodiment

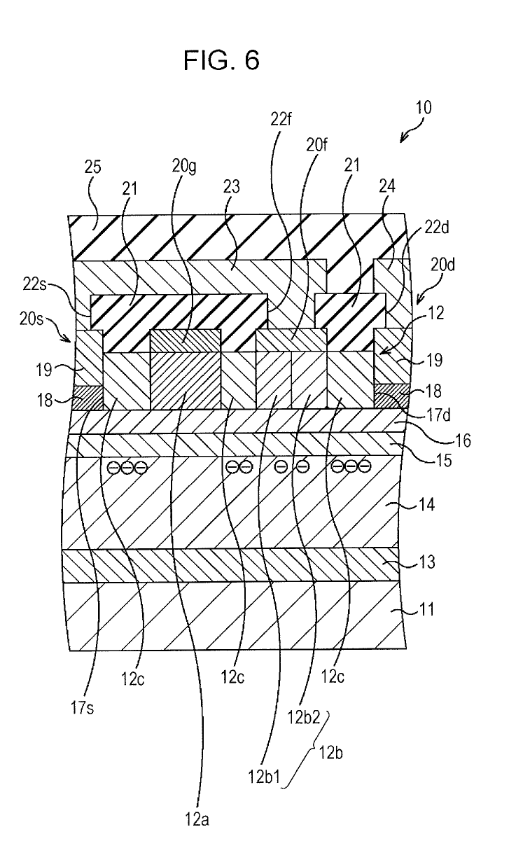

A third embodiment is described below. FIG. 6 is a sectional view of a compound semiconductor device according to the third embodiment.

In the third embodiment, a low-carrier concentration region 12b is defined into a first low-carrier concentration sub-region 12b1 and a second low-carrier concentration sub-region 12b2. The first low-carrier concentration sub-region 12b1 is located on the side of a gate electrode 20g. The second low-carrier concentration sub-region 12b2 is located on the side of a drain electrode 20d. The first low-carrier concentration sub-region 12b1 and the second low-carrier concentration sub-region 12b2 are those formed by activating Mg, which is a p-type impurity, contained in a Mg-doped compound semiconductor layer 12. The first low-carrier concentration sub-region 12b1 is more strongly activated than the second low-carrier concentration sub-region 12b2. Thus, the carrier concentration of the first low-carrier concentration sub-region 12b1 is higher than the carrier concentration of the second low-carrier concentration sub-region 12b2. Other members are substantially the same as those described in the second embodiment.

According to the third embodiment, the closer the low-carrier concentration region 12b is to the drain electrode 20d, the further the carrier concentration of the low-carrier concentration region 12b decreases stepwise; hence, the third embodiment may more readily suppress the concentration of an electric field as compared to the second embodiment. Thus, more increased dielectric strength may be achieved.

In order to obtain a structure according to the third embodiment, the irradiation of a laser beam may be performed twice at different irradiation intensities using, for example, two types of masks during the formation of the low-carrier concentration region 12b.

In the third embodiment, the carrier concentration of the low-carrier concentration region 12b varies in two steps and may vary in three or more steps.

### Fourth Embodiment

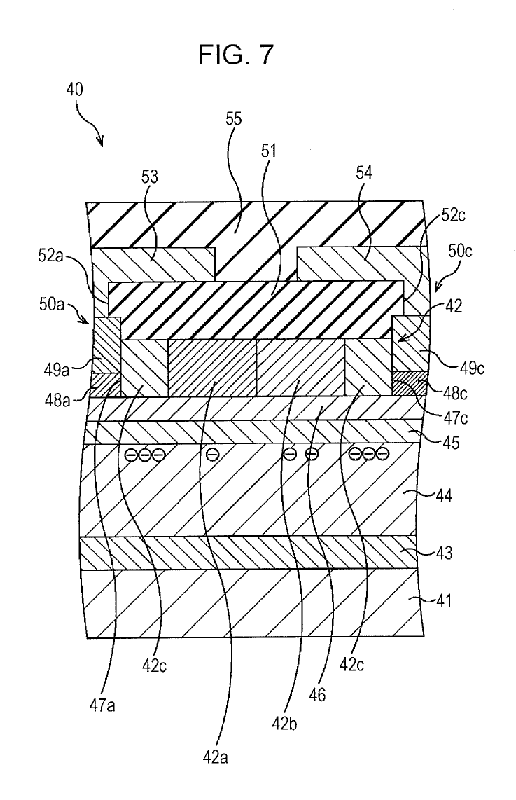

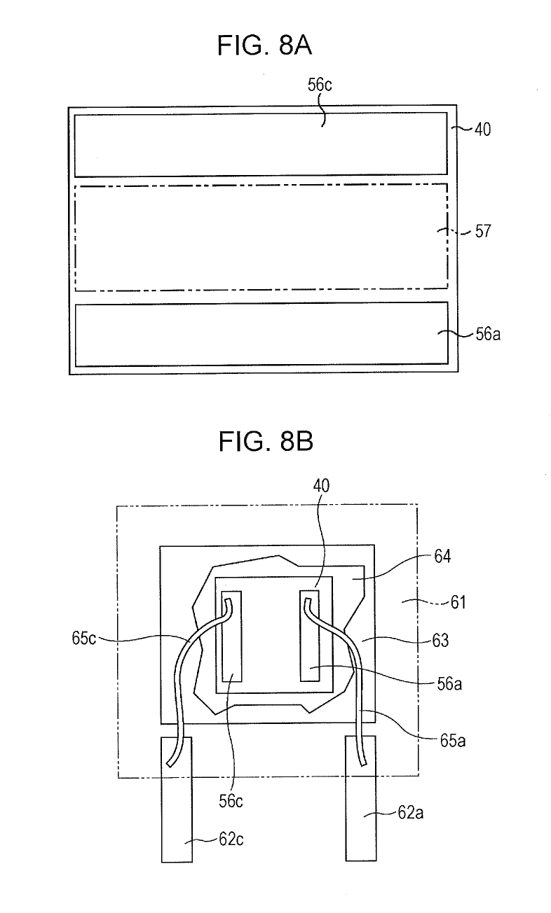

A fourth embodiment is described below. FIG. 7 is a sectional view of a compound semiconductor device according to the fourth embodiment. FIGS. 8A and 8B are full views of the compound semiconductor device according to the fourth embodiment.

In the compound semiconductor device 40 according to the fourth embodiment, a buffer layer 43, an electron travel layer 44, an intermediate layer 45, an electron supply layer 46, and a Mg-doped compound semiconductor layer 42 are arranged in series on a substrate 41 as illustrated in FIG. 7. The substrate 41, the buffer layer 43, the electron travel layer 44, the intermediate layer 45, the electron supply layer 46, and the Mg-doped compound semiconductor layer 42 are substantially the same as the substrate 11, buffer layer 13, electron travel layer 14, intermediate layer 15, electron supply layer 16, and Mg-doped compound semiconductor layer 12, respectively, described in the second embodiment.

The Mg-doped compound semiconductor layer 42 has openings 47a and 47c. The opening 47a contains an anode electrode 50a and the opening 47c contains a cathode electrode 50c. The anode electrode 50a includes a Ni film 48a in contact with the electron supply layer 46 and an Au film 49a disposed on the Ni film 48a. The cathode electrode 50c includes a Ta film 48c in contact with the electron supply layer 46 and an Al film 49c disposed on the Ta film 48c. The Mg-doped compound semiconductor layer 42 includes a high-carrier concentration region 42a and low-carrier concentration region 42b located between the anode electrode 50a and the cathode electrode 50c. The high-carrier concentration region 12a and the low-carrier concentration region 12b are in contact with each other. The high-carrier concentration region 42a and the low-carrier concentration region 42b are those formed by activating Mg, which is a p-type impurity, contained in the Mg-doped compound semiconductor layer 42. The high-carrier concentration region 42a is more strongly activated than the low-carrier concentration region 412b. Thus, the high-carrier concentration region 42a has a carrier concentration higher than the carrier concentration of the low-carrier concentration region 42b. The high-carrier concentration region 42a is located closer to the anode electrode 50a than the low-carrier concentration region 42b. Hence, the low-carrier concentration region 42b is located between the high-carrier concentration region 42a and the cathode electrode 50c. The Mg-doped compound semiconductor layer 42 further includes inactive regions 42c in which Mg is not activated. The inactive regions 42c are each located between the anode electrode 50a and the high-carrier concentration region 42a or between the low-carrier concentration region 42b and the cathode electrode 50c.

The Mg-doped compound semiconductor layer 42, the anode electrode 50a, and the cathode electrode 50c are covered with an insulating layer 51. The insulating layer 51 is, for example, a silicon nitride film. The insulating layer 51 has an opening 52a through which at least one portion of the anode electrode 50a is exposed and also has an opening 52c through which at least one portion of the cathode electrode 50c is exposed. A wiring line 53 connected to the anode electrode 50a and a wiring line 54 connected to the cathode electrode 50c extend on the insulating layer 51. A passivation layer 55 is disposed on the insulating layer 51 and covers the wiring lines 53 and 24. The passivation layer 55 is, for example, a silicon nitride film.

The compound semiconductor device 40, which is configured as described above, functions as a Schottky diode. That is, the anode electrode 50a is in Schottky contact with the electron travel layer 44, a 2DEG is generated in a surface portion of the electron travel layer 44, and a current flows between the anode electrode 50a and the cathode electrode 50c depending on the direction of an electric field formed between the anode electrode 50a and the cathode electrode 50c.

High dielectric strength may be achieved by the action of the high-carrier concentration region 42a and the low-carrier concentration region 42b.

As illustrated in FIG. 8A, the wiring line 53 is connected to an anode pad 56a which is an external terminal of the compound semiconductor device 40 and the wiring line 54 is connected to a cathode pad 56c which is an external terminal of the compound semiconductor device 40. A region located between the anode pad 56a and the cathode pad 56c in plan view substantially corresponds to a diode region 57 in which the 2DEG is present.

For packaging, as illustrated in FIG. 8B, the back surface of the compound semiconductor device 40 is fixed to a land 63 with a die attaching agent 64 such as solder. One end of a wire 65a such as an Al wire is connected to the anode pad 56a and the other end of the wire 65a is connected to an anode lead 62a independent of the land 63. One end of a wire 65c such as an Al wire is connected to the cathode pad 56c and the other end of the wire 65c is connected to a cathode lead 62c independent of the land 33. The land 63, the compound semiconductor device 40, and the like are packaged with a molding resin 61 such that a portion of the anode lead 62a and a portion of the cathode lead 62c protrude.

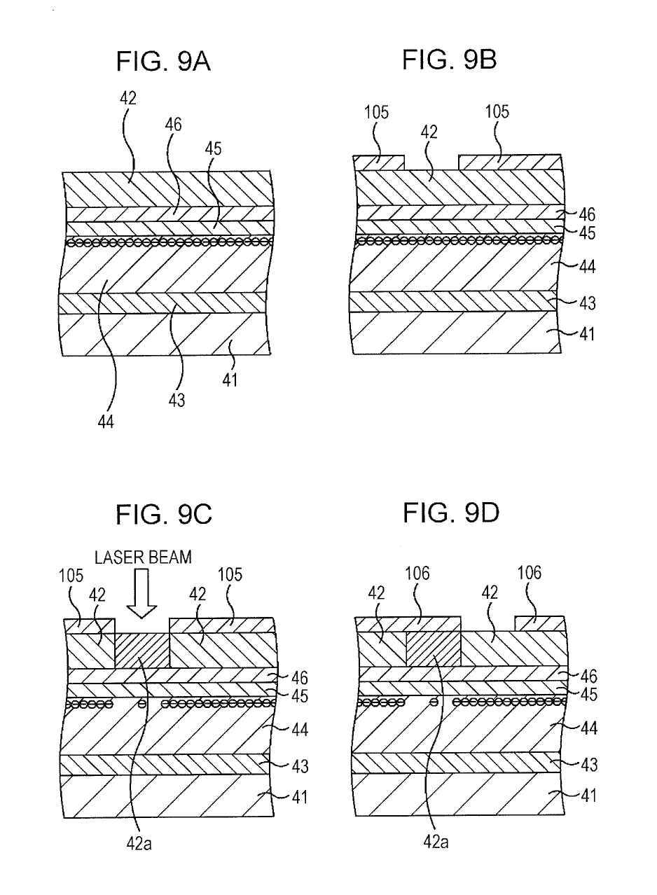

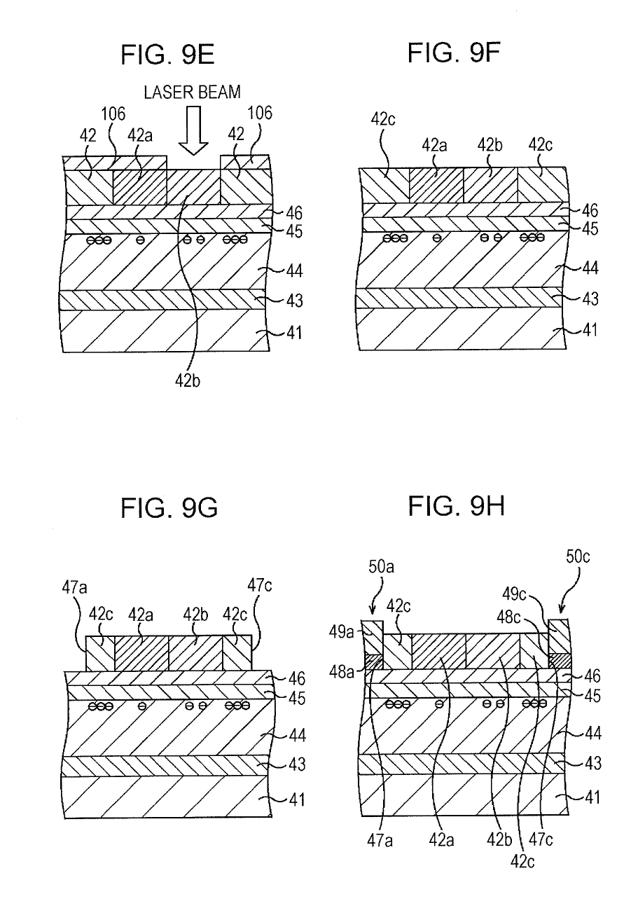

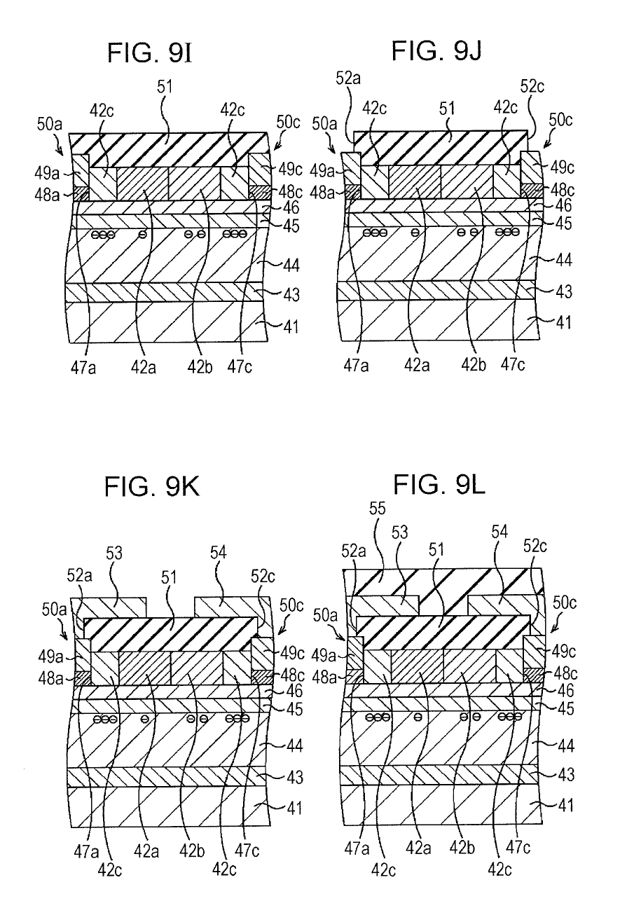

A method for manufacturing the compound semiconductor device 40 according to the fourth embodiment is described below. FIGS. 9A to 9L are sectional views illustrating operations of the method for manufacturing the compound semiconductor device 40 according to the fourth embodiment.

First, as illustrated in FIG. 9A, the buffer layer 43, the electron travel layer 44, the intermediate layer 45, the electron supply layer 46, and the Mg-doped compound semiconductor layer 42 are formed in series on the substrate 41 by, for example, a crystal growth process such as MOCVD or MBE. As a result, a 2DEG is generated in a surface portion of the electron travel layer 44 at high concentration. The buffer layer 43, the electron travel layer 44, the intermediate layer 45, the electron supply layer 46, and the Mg-doped compound semiconductor layer 42 may be formed in the same manner as that used to form the buffer layer 13, electron travel layer 14, intermediate layer 15, electron supply layer 16, and Mg-doped compound semiconductor layer 12 described in the second embodiment.

Next, as illustrated in FIG. 9B, a mask 105 such as a metal mask is formed on the Mg-doped compound semiconductor layer 42 so as to have an opening open to a region which is to be formed into the high-carrier concentration region 42a. As illustrated in FIG. 9C, the Mg-doped compound semiconductor layer 42 is irradiated with a laser beam through the opening of the mask 105. A source of the laser beam used is, for example, a KrF excimer laser. The irradiation intensity of the laser beam is, for example, about 175 mJ/cm². As a result, a portion of the Mg-doped compound semiconductor layer 42 that is irradiated with the laser beam is increased in temperature, Mg is activated, and therefore holes are generated. This portion is converted into the high-carrier concentration region 42a. Since the high-carrier concentration region 42a is formed, the concentration of the 2DEG under the high-carrier concentration region 42a is reduced.

Thereafter, as illustrated in FIG. 9D, the mask 105 is removed and a mask 106 such as a metal mask is then formed on the Mg-doped compound semiconductor layer 42 so as to have an opening open to a region which is to be formed into the low-carrier concentration region 42b. As illustrated in FIG. 9E, the Mg-doped compound semiconductor layer 42 is irradiated with a laser beam through this opening of the mask 106. A source of the laser beam used is, for example, a KrF excimer laser. In this operation, the irradiation intensity of the laser beam is lower than the irradiation intensity of the laser beam used to form the high-carrier concentration region 42a and is, for example, about 100 mJ/cm². As a result, a portion of the Mg-doped compound semiconductor layer 42 that is irradiated with the laser beam is increased in temperature, Mg in this portion is less activated than Mg in the portion used to form the high-carrier concentration region 42a, and therefore holes are generated at low concentration. This portion is converted into the low-carrier concentration region 42b. Since the low-carrier concentration region 42b is formed, the concentration of the 2DEG under the low-carrier concentration region 42b is reduced. However, the reduction in concentration of the 2DEG under the low-carrier concentration region 42b is lower than the reduction in concentration of the 2DEG under high-carrier concentration region 42a. Therefore, the concentration of the 2DEG under the low-carrier concentration region 42b is higher than the concentration of the 2DEG under high-carrier concentration region 42a.

Next, as illustrated in FIG. 9F, the mask 106 is removed. Portions of the Mg-doped compound semiconductor layer 42 that are irradiated with no laser beam and that contain no carriers correspond to the inactive regions 42c. As illustrated in FIG. 9G, the opening 47a for the anode electrode 50a and the opening 47c for the cathode electrode 50c are formed in the Mg-doped compound semiconductor layer 42. Thereafter, as illustrated in FIG. 9H, the anode electrode 50a and cathode electrode 50c are formed in the opening 47a and the opening 47c, respectively, by, for example, a lift-off process. The anode electrode 50a is formed in such a manner that the Ni film 48a and the Au film 49a are formed by, for example, a vapor deposition process. The cathode electrode 50c is formed in such a manner that the Ta film 48c and the Al film 49c are formed by, for example, a vapor deposition process.

Next, as illustrated in FIG. 91, the insulating layer 51 is formed over the Mg-doped compound semiconductor layer 42, the anode electrode 50a, and the cathode electrode 50c. Thereafter, as illustrated in FIG. 9J, the opening 52a and the opening 52c are formed in the insulating layer 51 such that at least one portion of the anode electrode 50a is exposed through the opening 52a and at least one portion of the cathode electrode 50c is exposed through the opening 52c. As illustrated in FIG. 9K, the wiring lines 53 and 54 are formed on the insulating layer 21 such that the wiring line 53 extends through the opening 52a to connect to the anode electrode 50a and the wiring line 54 extends through the opening 52c to connect to the cathode electrode 50c. As illustrated in FIG. 9L, the passivation layer 55 is then formed over the wiring lines 53 and 54.

As described above, the compound semiconductor device (diode chip) 40 may be manufactured so as to have a structure illustrated in FIG. 7.

### Fifth Embodiment

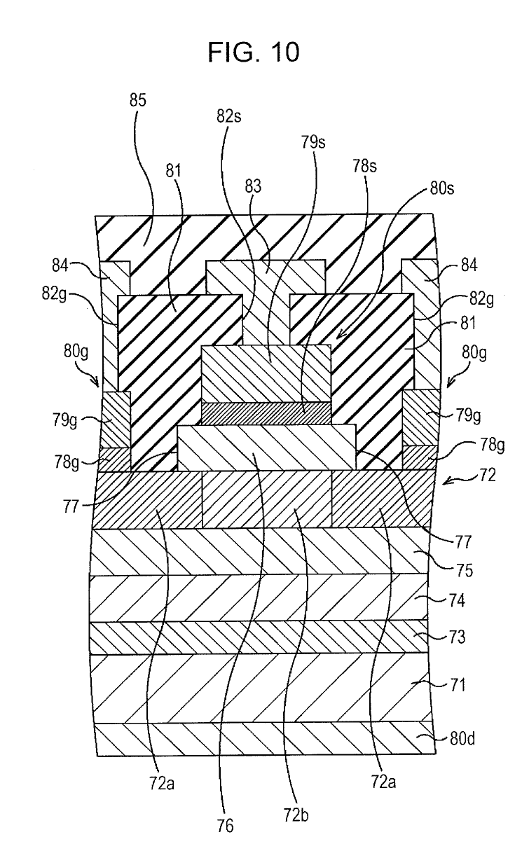

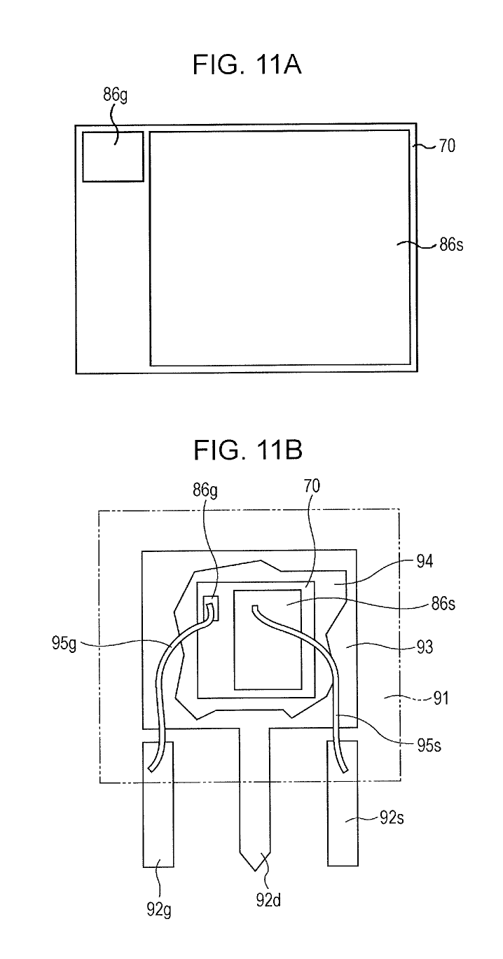

A fifth embodiment is described below. FIG. 10 is a sectional view of a compound semiconductor device according to the fifth embodiment. FIGS. 11A and 11B are full views of the compound semiconductor device according to the fifth embodiment.

In the compound semiconductor device 70 according to the fifth embodiment, a buffer layer 73, an n-type GaN layer 74, an n⁻GaN layer 75 containing an n-type impurity at lower concentration as compared to the n-type GaN layer 74, and a Mg-doped compound semiconductor layer 72 are arranged in series on a substrate 71 as illustrated in FIG. 10. The substrate 71, the buffer layer 73, and the Mg-doped compound semiconductor layer 72 are substantially the same as the substrate 11, buffer layer 13, and Mg-doped compound semiconductor layer 12, respectively, described in the second embodiment. The substrate 71 has low resistance. The n-type GaN layer 74 has a thickness of about 100 nm to 10,000 nm. The n⁻GaN layer 75 has a thickness of about 10 nm to 10,000 nm.

The Mg-doped compound semiconductor layer 72 includes a low-carrier concentration region 72b and a high-carrier concentration region 72a surrounding the low-carrier concentration region 72b in plan view. The Mg-doped compound semiconductor layer 72 is made of GaN doped with Mg at a concentration of about 1×10¹⁹ cm⁻³ and has a thickness of, for example, about 10 nm. The high-carrier concentration region 72a and the low-carrier concentration region 72b are those formed by activating Mg, which is a p-type impurity, contained in the Mg-doped compound semiconductor layer 72. The high-carrier concentration region 72a is more strongly activated than the low-carrier concentration region 72b. Thus, the high-carrier concentration region 72a has a carrier concentration higher than the carrier concentration of the low-carrier concentration region 72b.

The low-carrier concentration region 72b is overlaid with an n-type GaN layer 76. The n-type GaN layer 76 is overlaid with a source electrode 80s. The source electrode 80s includes a Ta film 78s in contact with the n-type GaN layer 76 and an Al film 79s disposed on the Ta film 78s. The high-carrier concentration region 72a is overlaid with a gate electrode 80g. The gate electrode 80g includes a Ni film 78g in contact with the high-carrier concentration region 72a and an Au film 79g disposed on the Ni film 78g. A drain electrode 80d is disposed on the back surface of the substrate 71. The drain electrode 80d includes a Ta film in contact with the substrate 71 and an Al film disposed on the Ta film.

The Mg-doped compound semiconductor layer 72, the source electrode 80s, and the gate electrode 20g are covered with an insulating layer 81. The insulating layer 81 is, for example, a silicon nitride film. The insulating layer 81 has an opening 82s through which at least one portion of the source electrode 80s is exposed and an opening 82g through which at least one portion of the gate electrode 80g is exposed. A wiring line 83 connected to the source electrode 80s and a wiring line 84 connected to the gate electrode 80g extend on the insulating layer 81. A passivation layer 85 is disposed on the insulating layer 81 and covers the wiring lines 83 and 84. The passivation layer 85 is, for example, a silicon nitride film.

The compound semiconductor device 70, which is configured as described above, functions as a vertical field-effect transistor. High dielectric strength may be achieved by the action of the high-carrier concentration region 72a and the low-carrier concentration region 72b.

As illustrated in FIG. 11A, the wiring line 83 is connected to a source pad 86s which is an external terminal of the compound semiconductor device 70 and the wiring line 84 is connected to a gate pad 86g which is an external terminal of the compound semiconductor device 70.

For packaging, as illustrated in FIG. 11B, the back surface of the compound semiconductor device 70 is fixed to a land 93 with a conductive die attaching agent 94 such as solder. One end of a wire 95s such as an Al wire is connected to the source pad 86s and the other end of the wire 95s is connected to a source lead 92s independent of the land 93. One end of a wire 95g such as an Al wire is connected to the gate pad 86g and the other end of the wire 95g is connected to a gate lead 92g independent of the land 93. The drain electrode 80d is fixed to the land 93 with the conductive die attaching agent 94 and is connected to a drain lead 92d integral with the land 93. The land 93, the compound semiconductor device 70, and the like are packaged with a molding resin 91 such that a portion of the gate lead 92g, a portion of the drain lead 92d, and a portion of the source lead 92s protrude.

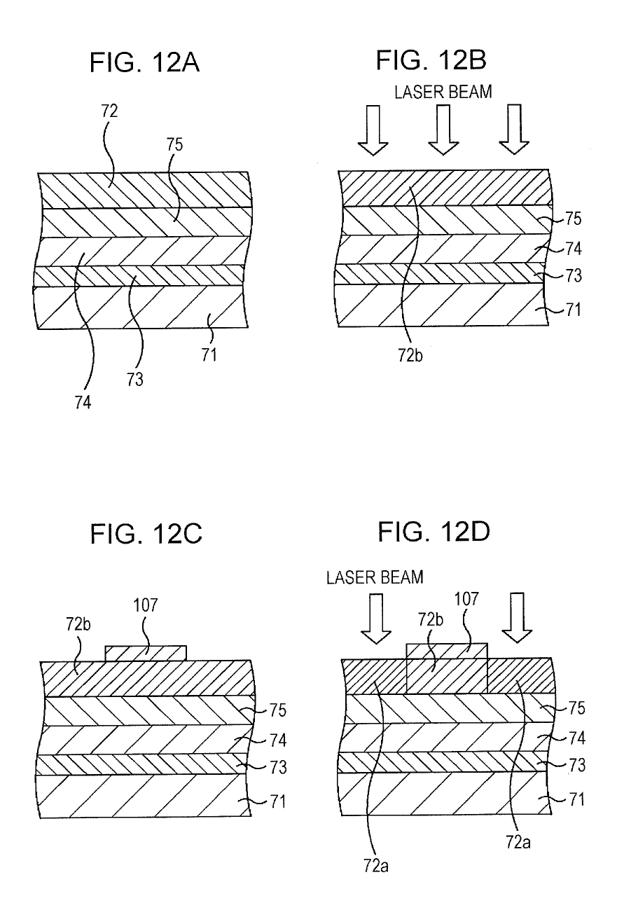

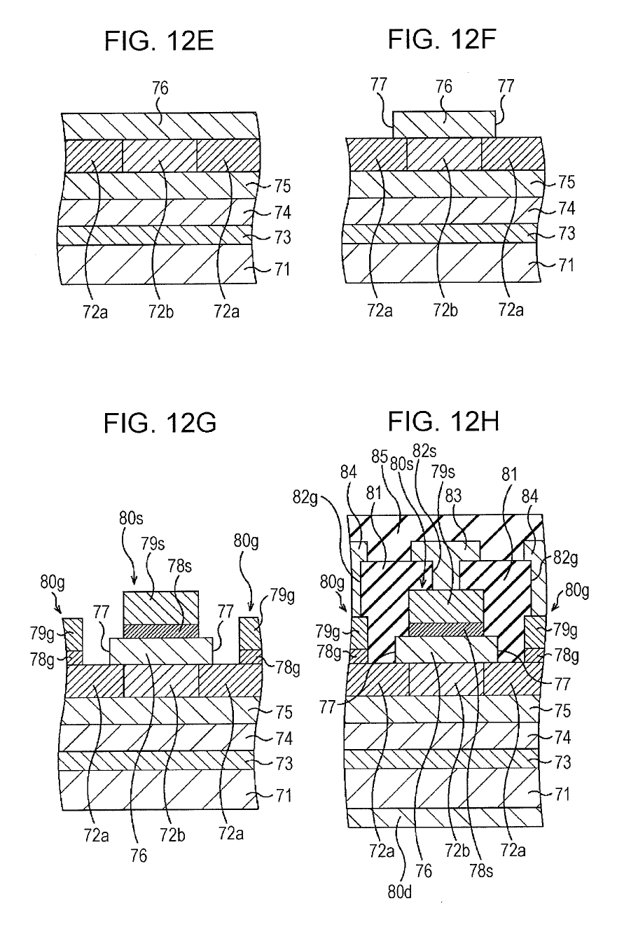

A method for manufacturing the compound semiconductor device 70 according to the fifth embodiment is described below. FIGS. 12A to 12H are sectional views illustrating operations of the method for manufacturing the compound semiconductor device 70 according to the fifth embodiment.

First, as illustrated in FIG. 12A, the buffer layer 73, the n-type GaN layer 74, the n⁻GaN layer 75, and the Mg-doped compound semiconductor layer 72 are formed in series on the substrate 71 by, for example, a crystal growth process such as MOCVD or MBE.

Next, as illustrated in FIG. 12B, the whole of the Mg-doped compound semiconductor layer 72 is irradiated with a laser beam. A source of the laser beam used is, for example, a KrF excimer laser. The irradiation intensity of the laser beam is, for example, about 100 mJ/cm². As a result, the whole of the Mg-doped compound semiconductor layer 42 is increased in temperature, Mg is activated, and therefore holes are generated. The whole of the Mg-doped compound semiconductor layer 72 is converted into the low-carrier concentration region 72b.

Thereafter, as illustrated in FIG. 12C, a mask 107 such as a metal mask is formed on the low-carrier concentration region 72b so as to have an opening open to a region which is to be formed into the high-carrier concentration region 72a. As illustrated in FIG. 12D, the low-carrier concentration region 72b is irradiated with a laser beam through the opening of the mask 107. A source of the laser beam used is, for example, a KrF excimer laser. The irradiation intensity of the laser beam is higher than the irradiation intensity of the laser beam used to form the low-carrier concentration region 72b and is, for example, about 250 mJ/cm². As a result, a portion of the low-carrier concentration region 72b that is irradiated with the laser beam is increased in temperature, Mg is activated again, and therefore holes are further generated. This portion is converted into the high-carrier concentration region 72a.

Next, as illustrated in FIG. 12E, the mask 107 is removed and the n-type GaN layer 76 is then formed over the high-carrier concentration region 72a and the low-carrier concentration region 72b by, for example, a crystal growth process such as MOCVD or MBE. As illustrated in FIG. 12F, an opening 77 is formed in the n-type GaN layer 76 such that at least one portion of the high-carrier concentration region 72a is exposed through the opening 77.

Thereafter, as illustrated in FIG. 12G, the gate electrode 80g is formed in the opening 77 and the source electrode 80s formed on the n-type GaN layer 76 by, for example, a lift-off process. The gate electrode 80g is formed in such a manner that the Ni film 78g and the Au film 79g are formed by, for example, a vapor deposition process. The source electrode 80s is formed in such a manner that the Ta film 78s and the Al film 79s are formed by, for example, a vapor deposition process.

Next, as illustrated in FIG. 12H, the insulating layer 81 is formed over the source electrode 80s, the gate electrode 80g, and the like. The opening 82s and the opening 82g are formed in the insulating layer 81 such that at least one portion of the source electrode 80s is exposed through the opening 82s and at least one portion of the gate electrode 80g is exposed through the opening 82g. The wiring line 83 and the wiring line 84 are formed on the insulating layer 81 such that the wiring line 83 is connected to the source electrode 80s through the opening 82s and the wiring line 84 is connected to the gate electrode 80g through the opening 82g. The passivation layer 85 is then formed over the wiring lines 83 and 84.

As described above, the compound semiconductor device (transistor chip) 70 may be manufactured so as to have a structure illustrated in FIG. 10.

### Sixth Embodiment

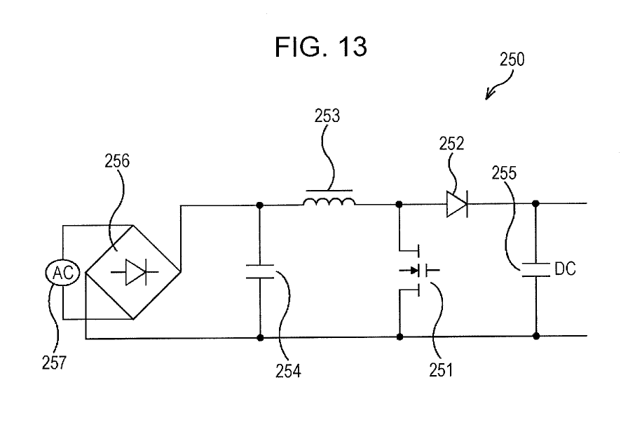

A sixth embodiment is described below. The sixth embodiment is related to a power factor correction (PFC) circuit including the compound semiconductor device according to the second or third embodiment. FIG. 13 is a wiring diagram of the PFC circuit according to the sixth embodiment.

The PFC circuit 250 includes a switching element (transistor) 251, a diode 252, a choke coil 253, capacitors 254 and 255, a diode bridge 256, and an alternating-current (AC) power supply 257. A drain electrode of the switching element 251 is connected to an anode terminal of the diode 252 and a terminal of the choke coil 253. A source electrode of the switching element 251 is connected to a terminal of the capacitor 254 and a terminal of the capacitor 255. Another terminal of the capacitor 255 is connected to a cathode terminal of the diode 252. The AC power supply 257 is connected to the two terminals of the capacitor 254 with the diode bridge 256 placed therebetween. The two terminals of the capacitor 255 are connected to a direct-current (DC) power supply. In this embodiment, the switching element 251 includes compound semiconductor device according to the second or third embodiment.

In this embodiment, further increased dielectric strength may be achieved and an AlGaN/GaN-HEMT enabling the increase in operation speed of devices may be applied to the PFC circuit 250. Thus, the PFC circuit 250 has high reliability.

### Seventh Embodiment

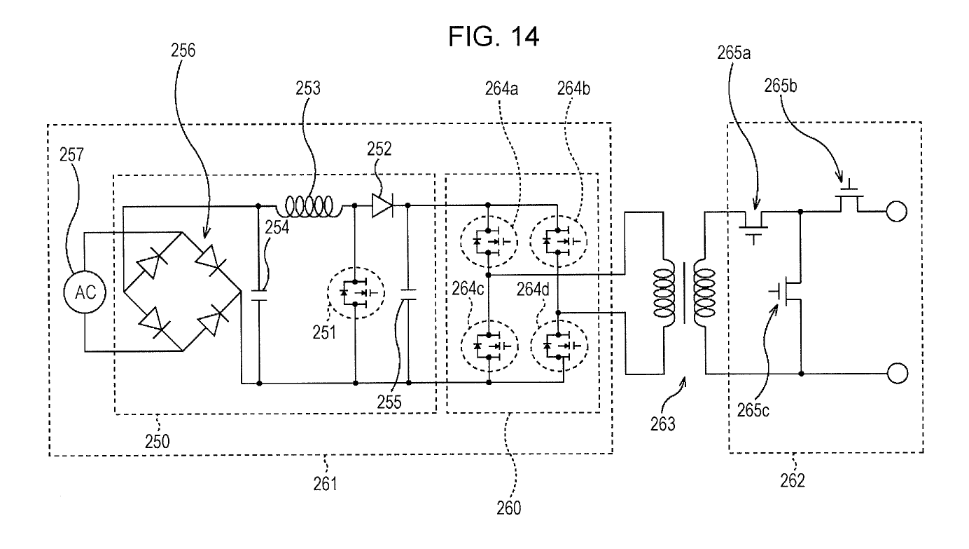

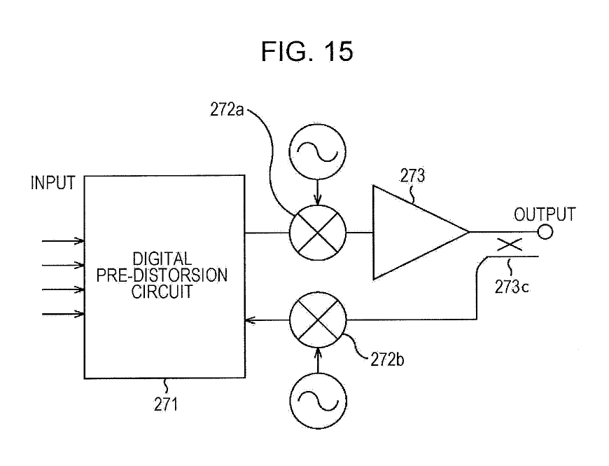

A seventh embodiment is described below. The seventh embodiment is related to a power supply system including the compound semiconductor device according to the second or third embodiment. FIG. 14 is a wiring diagram of the power supply system according to the seventh embodiment.

The power supply system includes a high-voltage primary circuit 261, a low-voltage secondary circuit 262, and a transformer 263 placed between the primary circuit 261 and the secondary circuit 262.

The primary circuit 261 includes the PFC circuit 250 according to the sixth embodiment and, for example, a full-bridge inverter circuit 260 connected to two terminals of the capacitor 255 of the PFC circuit 250. The full-bridge inverter circuit 260 includes a plurality of switching elements 264a, 264b, 264c, and 264d (herein, the number thereof is four).

The secondary circuit 262 includes a plurality of switching elements 265a, 265b, and 265c (herein, the number thereof is three).

In this embodiment, HEMTs corresponding to the compound semiconductor device according to the second or third embodiment are used in the switching element 251 of the PFC circuit 250, which is included in the primary circuit 261, and the switching elements 264a, 264b, 264c, and 264d of the full-bridge inverter circuit 260. Common metal-insulator-semiconductor field-effect transistors (MISFETs) made of silicon are used in the switching elements 265a, 265b, and 265c of the secondary circuit 262.

In this embodiment, further increased dielectric strength may be achieved and AlGaN/GaN-HEMTs which enable the increase in operation speed of devices and which have high reliability and high dielectric strength may be applied to the primary circuit 261, which is a high-voltage circuit. Thus, the power supply system has high reliability and high power.

### Eighth Embodiment

An eighth embodiment is described below. The eighth embodiment is related to a high-frequency amplifier including the compound semiconductor device according to the second or third embodiment. FIG. 15 is a wiring diagram of the high-frequency amplifier according to the eighth embodiment.

The high-frequency amplifier includes a digital pre-distortion circuit 271, mixers 272a and 272b, and a power amplifier 273.

The digital pre-distortion circuit 271 compensates for the non-linear distortion of an input signal. The mixer 272a mixes an alternating-current signal with the input signal of which the non-linear distortion is compensated for. The power amplifier 273 includes the compound semiconductor device according to the second or third embodiment and amplifies the input signal mixed with the alternating-current signal. In this embodiment, for example, an output signal may be inputted to the mixer 272b by switching on the switch 273c, the output signal may be mixed with the alternating-current signal by the mixer 272b and may be transmitted to the digital pre-distortion circuit 271 by switching.

In this embodiment, further increased dielectric strength may be achieved and an AlGaN/GaN-HEMT enabling the increase in operation speed of devices may be applied to the high-frequency amplifier. Thus, the high-frequency amplifier has high reliability.

Experiments performed by the inventor for the purpose of confirming advantages of the above embodiments are described below.

(First Experiment)

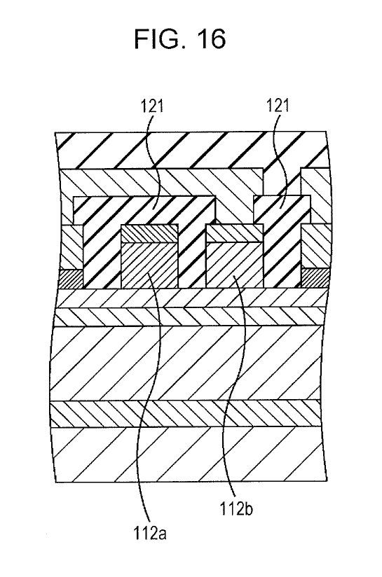

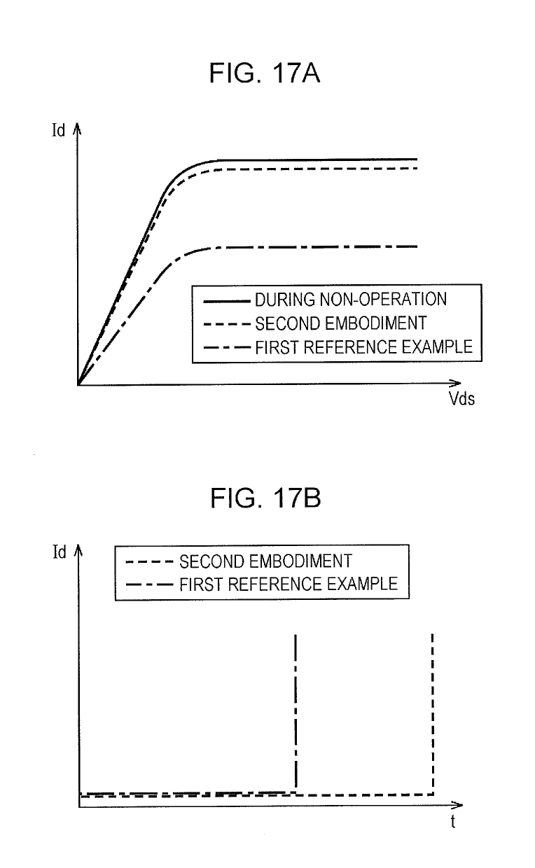

In a first experiment, the second embodiment and a first reference example illustrated in FIG. 16 were investigated for the relationship between the drain-source voltage Vds and the drain current Id and the time t taken to cause breakdown in the case of applying a voltage between a drain and a source. Obtained results are illustrated in FIGS. 17A and 17B. A high-carrier concentration region 112a and low-carrier concentration region 112b of the first reference example were formed in such a manner that after a Mg-doped GaN layer for forming the high-carrier concentration region 112a was formed, was etched, and was annealed, a Mg-doped GaN layer for forming the low-carrier concentration region 112b was formed, was etched, and was then annealed. Thus, no inactive region was present. Instead of the insulating layer 21, an insulating layer 121 was formed so as to be in contact with an electron supply layer.

As illustrated in FIG. 17A, in the second embodiment, the drain current Id during operation is substantially equal to that during non-operation. However, in the first reference example, the drain current Id during operation is significantly less than that during non-operation. This is because the electron supply layer was damaged during the etching of the two Mg-doped GaN layers and therefore a large number of traps were formed. That is, according to the second embodiment, a reduction in current due to current collapse may be suppressed.

As illustrated in FIG. 17B, the time taken to cause breakdown in the second embodiment is longer than that in the first reference example. This is because the interface between the insulating layer 21 and the Mg-doped compound semiconductor layer 12 in the second embodiment is further away from a 2DEG as compared to the interface between the insulating layer 121 and the compound semiconductor layer in the first reference example and therefore the dielectric strength is increased. That is, according to the second embodiment, increased reliability may be achieved.

Thus, according to the second embodiment, an increase in on-resistance during operation is suppressed and an AlGaN/GaN-HEMT having high reliability and high dielectric strength is achieved. This applies to the third embodiment.

(Second Experiment)

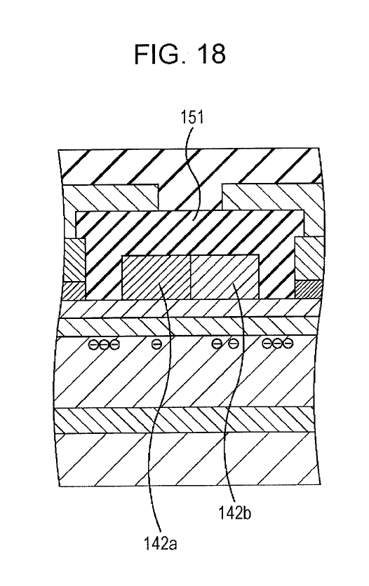

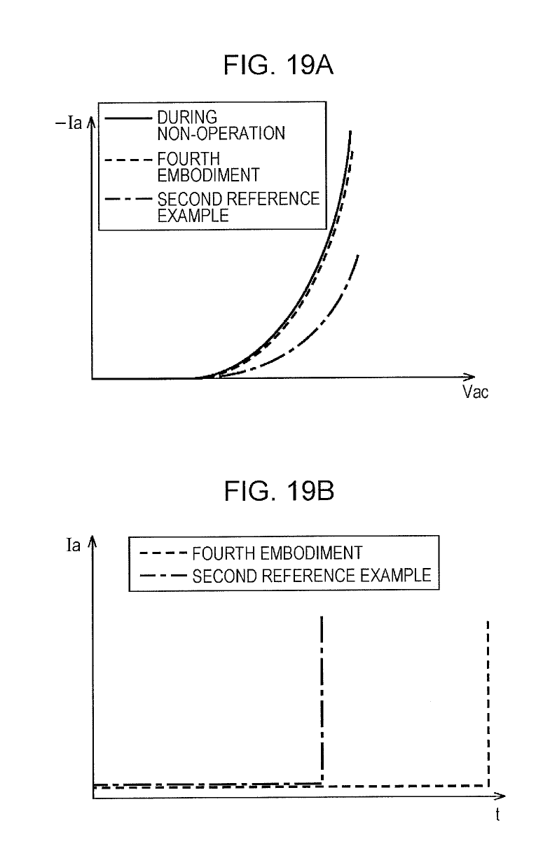

In a second experiment, the fourth embodiment and a second reference example illustrated in FIG. 18 were investigated for the relationship between the anode-cathode forward voltage Vac and the anode current Ia and the time t taken to cause breakdown in the case of applying a reverse voltage between an anode and a cathode. Obtained results are illustrated in FIGS. 19A and 19B. A high-carrier concentration region 142a and low-carrier concentration region 142b of the second reference example were formed in such a manner that after a Mg-doped GaN layer for forming the high-carrier concentration region 142a was formed, was etched, and was annealed, a Mg-doped GaN layer for forming the low-carrier concentration region 142b was formed, was etched, and was then annealed. Thus, no inactive region was present. Instead of the insulating layer 51, an insulating layer 151 was formed so as to be in contact with an electron supply layer.

As illustrated in FIG. 19A, in the fourth embodiment, the anode current Ia during operation is substantially equal to that during non-operation. However, in the second reference example, the anode current Ia during operation is significantly less than that during non-operation. This is because the electron supply layer was damaged during the etching of the two Mg-doped GaN layers and therefore a large number of traps were formed. That is, according to the second embodiment, a reduction in current due to current collapse may be suppressed.

As illustrated in FIG. 19B, the time taken to cause breakdown in the fourth embodiment is longer than that in the second reference example. This is because the interface between the insulating layer 51 and the Mg-doped compound semiconductor layer 42 in the fourth embodiment is further away from a 2DEG as compared to the interface between the insulating layer 151 and the compound semiconductor layer in the second reference example and therefore the dielectric strength is increased. That is, according to the fourth embodiment, increased reliability may be achieved.

Thus, according to the fourth embodiment, an increase in on-resistance during operation is suppressed and an AlGaN/GaN high-electron mobility diode having high reliability and high dielectric strength is achieved.

(Third Experiment)

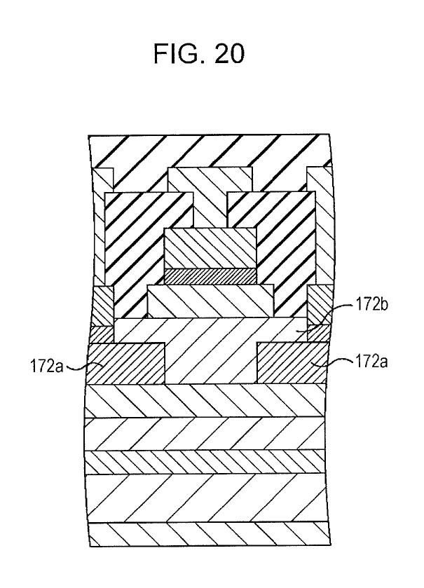

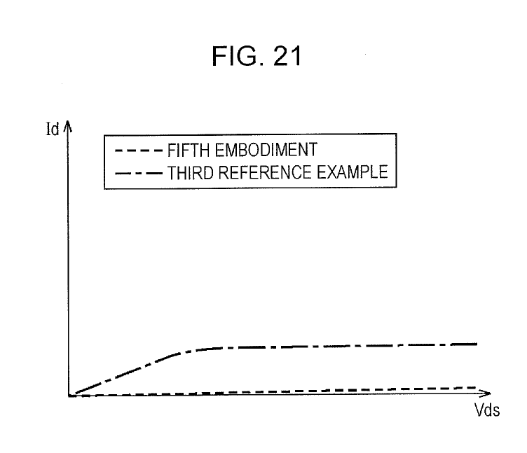

In a third experiment, the fifth embodiment and a third reference example illustrated in FIG. 20 were investigated for the relationship between the drain-source voltage Vds and the drain current Id during an off state. Obtained results are illustrated in FIG. 21. A high-carrier concentration region 172a of the third reference example was formed in such a manner that after a Mg-doped GaN layer for forming the high-carrier concentration region 172a was formed, was etched, and was annealed, an intentionally undoped GaN layer 172b was formed instead of the low-carrier concentration region 72b.

As illustrated in FIG. 21, in the fifth embodiment, substantially no drain current Id flew during the off state; however, in the third reference example, a drain current Id flew during the off state. That is, in the fifth embodiment, a normally-off operation was achieved; however, in the third reference example, a normally-off operation was incapable of being achieved.

Thus, according to the fifth embodiment, a transistor operating in a normally-off mode is achieved.

An impurity (a first or second impurity) contained in a compound semiconductor layer in which carriers are generated by the irradiation of a laser beam or the like is not limited to Mg and may be C in the case of generating, for example, holes or Si in the case of generating, for example, electrons.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A compound semiconductor device, comprising:
a substrate; and
a compound semiconductor layer disposed over the substrate,
wherein the compound semiconductor layer includes a first region having first conductivity-type carriers generated by activating a first impurity and also includes a second region having carriers at lower concentration as compared to the first region, the carriers being generated by activating a second impurity which is the same type as the first impurity.

2. The compound semiconductor device according to claim 1, wherein the first conductivity-type carriers are holes.

3. The compound semiconductor device according to claim 2, wherein the first impurity and the second impurity are Mg or C or Mg+C.

4. The compound semiconductor device according to claim 1, further comprising:
an electron travel layer located between the substrate and the compound semiconductor layer;
an electron supply layer located between the electron travel layer and the compound semiconductor layer;
a source electrode located over the electron travel layer;
a drain electrode located over the electron travel layer; and
a gate electrode located over the first region,
wherein the second region is located between the gate electrode and the drain electrode in plan view.

5. The compound semiconductor device according to claim 4, further comprising a field plate electrode located over the second region.

6. The compound semiconductor device according to claim 1, further comprising:
an electron travel layer located between the substrate and the compound semiconductor layer;
an electron supply layer located between the electron travel layer and the compound semiconductor layer;
an anode electrode located over the electron travel layer; and
a cathode electrode located over the electron travel layer,
wherein the first region and the second region are located between the anode electrode and the cathode electrode in plan view such that the first region is located on the anode electrode side and the second region is located on the cathode electrode side.

7. The compound semiconductor device according to claim 1, further comprising:
a lower compound semiconductor layer which is located between the substrate and the compound semiconductor layer and which has second conductivity-type carriers;
a gate electrode located over the first region;
a source electrode located over the second region;
an upper compound semiconductor layer which is located between the second region and the source electrode and which has the second conductivity-type carriers; and
a drain electrode located under the substrate.

8. A power supply system including a compound semiconductor device, the compound semiconductor device comprising:
a substrate; and
a compound semiconductor layer disposed over the substrate,
wherein the compound semiconductor layer includes a first region having first conductivity-type carriers generated by activating a first impurity and also includes a second region having carriers at lower concentration as compared to the first region, the carriers being generated by activating a second impurity which is the same type as the first impurity.

9. A high-frequency amplifier including a compound semiconductor device, the compound semiconductor device comprising:
a substrate; and
a compound semiconductor layer disposed over the substrate,
wherein the compound semiconductor layer includes a first region having first conductivity-type carriers generated by activating a first impurity and also includes a second region having carriers at lower concentration as compared to the first region, the carriers being generated by activating a second impurity which is the same type as the first impurity.

10. A method for manufacturing a compound semiconductor device, comprising:
forming a compound semiconductor layer having an impurity over a substrate;
generating first conductivity-type carriers in such a manner that a first region of the compound semiconductor layer is irradiated with a laser beam at a first irradiation intensity and thereby the impurity in the first region is activated; and
generating the first conductivity-type carriers in such a manner that a second region of the compound semiconductor layer that is different from the first region is irradiated with a laser beam at a second irradiation intensity that is different from the first irradiation intensity and thereby the impurity in the second region is activated.

11. The method according to claim 10, wherein the first conductivity-type carriers are holes.

12. The method according to claim 11, wherein the impurity is Mg or C.

13. The method according to claim 10, further comprising: prior to forming of the compound semiconductor layer,
forming an electron travel layer over the substrate;
forming an electron supply layer over the electron travel layer;
forming a source electrode and a drain electrode over the electron travel layer; and
forming a gate electrode over the first region after forming the compound semiconductor layer,
wherein the second region is located between the gate electrode and the drain electrode in plan view.

14. The method according to claim 13, further comprising forming a field plate electrode over the second region.

15. The method according to claim 10, further comprising: prior to forming the compound semiconductor layer,
forming an electron travel layer over the substrate;
forming an electron supply layer over the electron travel layer; and
forming an anode electrode and a cathode electrode over the electron travel layer;
wherein the first region and the second region are located between the anode electrode and the cathode electrode in plan view such that the first region is located on the anode electrode side and the second region is located on the cathode electrode side.

16. The method according to claim 10, further comprising:,
forming a lower compound semiconductor layer having second conductivity-type carriers over the substrate prior to forming the compound semiconductor layer;
forming a gate electrode located over the first region;
forming an upper compound semiconductor layer having the second conductivity-type carriers over the second region;
forming a source electrode over the upper compound semiconductor layer; and
forming a drain electrode under the substrate.
